(19) United States
(12) Patent Application Publication
(10) Pub. No.: US 2026/0338971 A1
(43) Pub. Date: Oct. 29, 2026

(54) BENDABLE DIGITAL RADIOGRAPHIC DETECTOR

(71) Applicant: CARESTREAM HEALTH, INC., Rochester, NY (US)

(72) Inventors: Anthony DIRISIO, Rochester, NY (US); Michael P. URBON, Rochester, NY (US); Michael K. Rogers, Mendon, NY (US)

(21) Appl. No.: 19/656,101

(22) Filed: Apr. 23, 2026

Related U.S. Application Data
(60) Provisional application No. 63/793,808, filed on Apr. 24, 2025.

(51) Int. Cl. G01T 1/20; H05K 1/189

(52) U.S. Cl. CPC G01T 1/20184; G01T 1/2002; G01T 1/20186; G01T 1/20187; G01T 1/20189; H05K 1/189; H05K 2201/10151

(57) ABSTRACT

A flexible digital radiographic detector with a plurality of rigid backbones allows the detector to bend around a first axis and prevents bending around a second axis perpendicular to the first axis. Flexible laminated layers include an imaging sensor layer. An elastomeric protective layer encloses the laminated layers and a portion of the readout electronics.

### CROSS REFERENCE TO RELATED APPLICATIONS

This application claims priority to U.S. Patent Application Serial No. 63/793,808, filed Apr. 24, 2025, in the name of Dirisio et al., and entitled BENDABLE DIGITAL RADIOGRAPHIC DETECTOR, which is hereby incorporated by reference as if fully set forth herein in its entirety.

This application is related in certain respects to U.S. Pat. No. 11,061,153, issued Jul. 13, 2021, in the name of Jadrich et al., and entitled FLEXIBLE DIGITAL RADIOGRAPHY DETECTOR which is hereby incorporated by reference as if fully set forth herein in its entirety.

### BACKGROUND OF THE INVENTION

The subject matter disclosed herein relates to a flexible or bendable digital radiographic (DR) detector capable of being wrapped around an object, such as a pipe, having a diameter as small as about two inches, for radiographically imaging the object. Such a detector is capable of withstanding radiation from long exposure times, from gamma radiation, cobalt sources, and is water & dust tight (IP67 rated) and has a protective exoskeleton that can survive a harsh industrial environment that it may be used in.

The discussion above is merely provided for general background information and is not intended to be used as an aid in determining the scope of the claimed subject matter.

### BRIEF DESCRIPTION OF THE INVENTION

A flexible digital radiographic detector with a plurality of rigid backbones allows the detector to bend around a first axis and prevents bending around a second axis perpendicular to the first axis. Flexible laminated layers include an imaging sensor layer. An elastomeric protective layer protects the laminated layers and a portion of the readout electronics. An advantage that may be realized in the practice of some disclosed embodiments of the flexible digital radiographic detector is imaging manufactured objects having a diameter as small as about two inches.

In one embodiment, a flexible digital radiography detector includes a plurality of adjacent rigid backbones on its back side and a plurality of flexible laminated layers including an imaging sensor layer, wherein an imaging side of the imaging sensor layer faces away from the back side. Readout electronics are electrically attached to the imaging sensor layer and folded onto the back side of the detector. The plurality of rigid backbones are configured to allow the flexible digital radiographic detector to bend around a first axis and to prevent the flexible digital radiographic detector from bending around a second axis perpendicular to the first axis.

The summary descriptions above are not meant to describe individual separate embodiments whose elements are not interchangeable. In fact, many of the elements described as related to a particular embodiment can be used together with, and possibly interchanged with, elements of other described embodiments. Many changes and modifications may be made within the scope of the present invention without departing from the spirit thereof, and the invention includes all such modifications.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings below are intended to be drawn neither to any precise scale with respect to relative size, angular relationship, relative position, or timing relationship, nor to any combinational relationship with respect to interchangeability, substitution, or representation of a required implementation, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIGS. 1A, 1B and 1C illustrate different views of one embodiment of a flexible, bendable, digital radiographic (DR) detector;

FIG. 2 is a perspective view of FIG. 1B including a connected PCB containing electronics for reading out image data from the bendable digital radiographic detector;

FIG. 3A is a cross section side view of the bendable DR detector including a protective enclosure, and FIG. 3B is a cross section side view of the bendable DR detector of FIG. 3A wrapped around a pipe;

FIGS. 4A-4B illustrate close up cross-section side views of components of the bendable DR detector;

FIG. 5 is a close-up cross-section side view of a portion of the bendable DR detector;

FIGS. 6A-6B are cross section side views of portions of the bendable DR detector wrapped around a pipe;

FIG. 7 is a close-up cross-section side view of a portion of the bendable DR detector wrapped around a pipe;

FIG. 8 is a cross section front view of the bendable DR detector;

FIG. 9 is a cross section side view of the bendable DR detector with a PCB housing attached;

FIGS. 10A-10B are perspective views of the bendable DR detector;

FIGS. 10C-10D are perspective views of the bendable DR detector of FIGS. 10A-10B, respectively, including a protective exoskeleton;

FIG. 11A is a close-up cross section side view of the PCB housing end of the bendable DR detector of FIG. 10C, and FIG. 11B is a cross section side view of the bendable DR detector wrapped around a pipe;

FIG. 12 is a cross section side view of an opposite end of the bendable DR detector of FIG. 11A; and

FIG. 13 is a front view of the bendable detector of FIG. 10C with end cap removed.

### DETAILED DESCRIPTION OF THE INVENTION

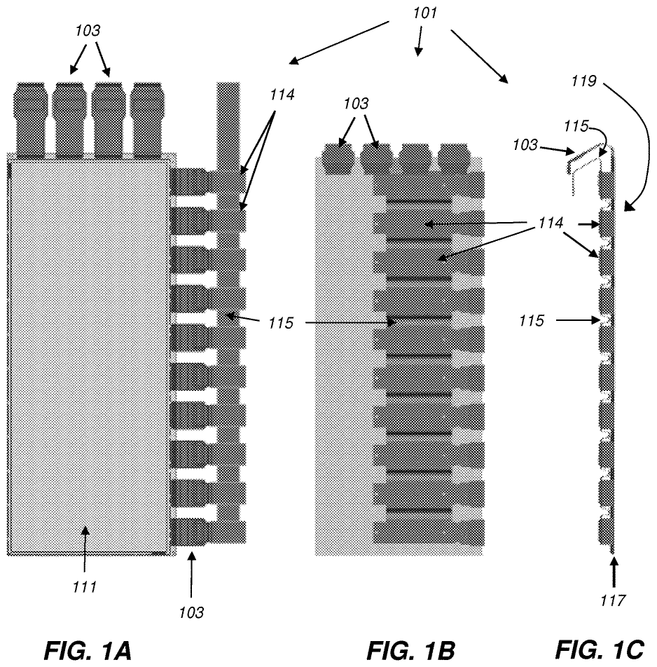

FIGS. 1A and 1B show a back side view of flexible, bendable DR detector 101 with chip-on-flex (CoF) connectors 103 electrically connected thereto. Row read out circuitry, boards, or electronics, 114 are connected to the CoF connectors on one side of the DR detector 101 outboard of the imaging area 111 of the DR detector 101. The imaging side of the DR detector 101 is opposite the back side shown, comprising an imaging layer 117, with an imaging surface having an area 111 on the front imaging side 119 of the DR detector 101 as shown in the side view of FIG. 1C. The row read out boards 114 are connected to the imaging layer 117 using the CoF connectors 103. As shown in FIG. 1B the row read out boards 114 and CoFs are folded over onto the backside of the DR detector 101 to maintain a compact size of the DR detector 101. In addition, flex connector 115 containing a plurality of insulated parallel conductors, electrically interconnect the row read out electronics 114 which may be fabricated as boards or chips, and so may be referred to herein as row driver boards, row read out boards, or row driver electronics, 114. FIG. 1C shows a side view of the DR detector 101 of FIG. 1B including the folded over row read out electronics 114.

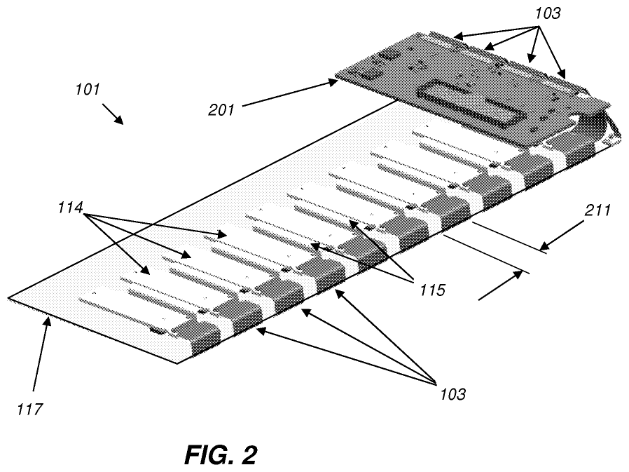

FIG. 2 shows a perspective view of the flexible, bendable DR detector 101 with a printed circuit board 201 electrically connected to column read out CoFs 103 at one end of the DR detector 101, as well to the row read out boards 114 via flex connector 115, for controlling image data read out from the DR detector's imaging sensor layer 117. Row driver electronics 114 are shown connected to imaging pixels in the imaging layer 117 on an opposite side of the DR detector 101 using CoF connectors 103 along one side of the DR detector 101. The row driver electronics 114 are similarly connected to PCB 201 via flex connector 115 (connection not visible in FIG. 2), as shown in FIG. 9. The row driver boards 114 may be fabricated to desired widths 211, such that smaller widths 211 may accommodate wrapping the flexible DR detector 101 around smaller diameter objects.

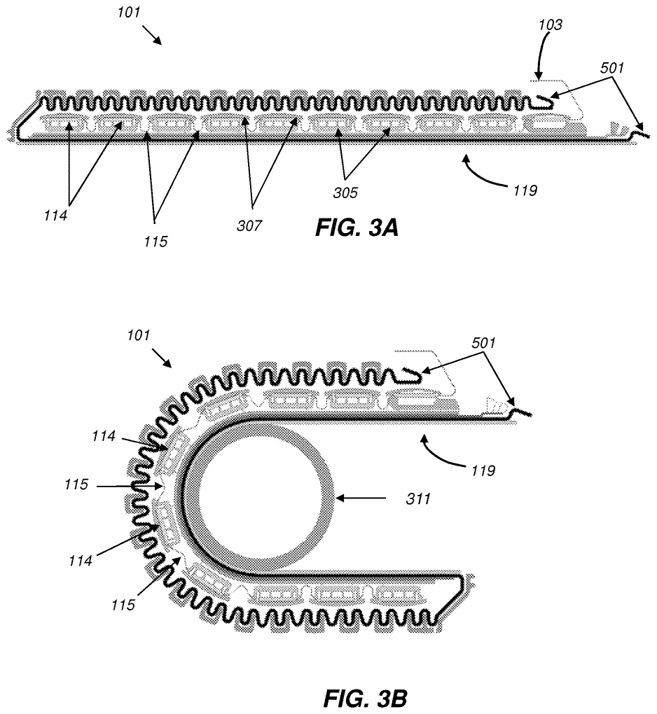

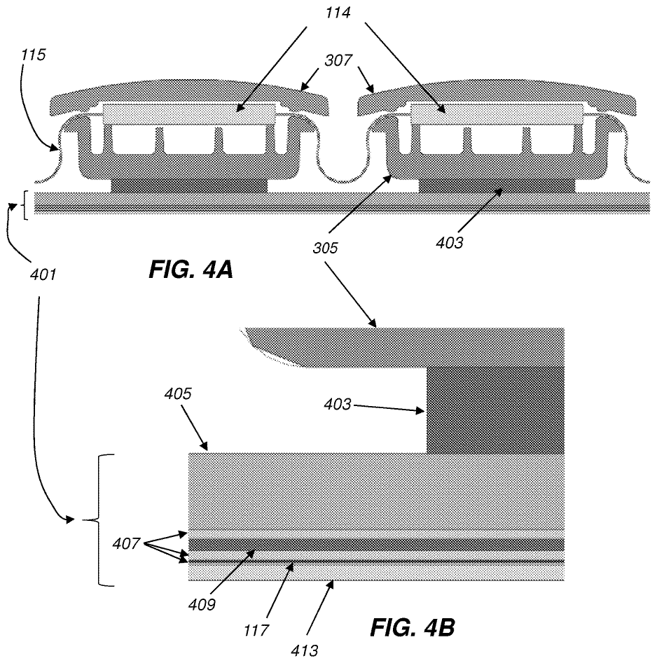

FIGS. 3A-3B show cross-section side views of the DR detector 101 lying flat and wrapped around an object, such as a two inch diameter pipe 311, respectively, with imaging side 119 in contact with the pipe 311. As the bendable DR detector 101 wraps around the pipe 311 the row read out boards 114 adjacent the pipe 311 move away from each other, as the flex connector 115 is configured with some slack so as to be extensible, as shown in FIG. 3B, and so accommodates this increased separation of the read out boards 114. Each read out board 114 is secured to a board mount 305 and enclosed by a cover 307, as shown in more detail in FIGS. 4A-4B.

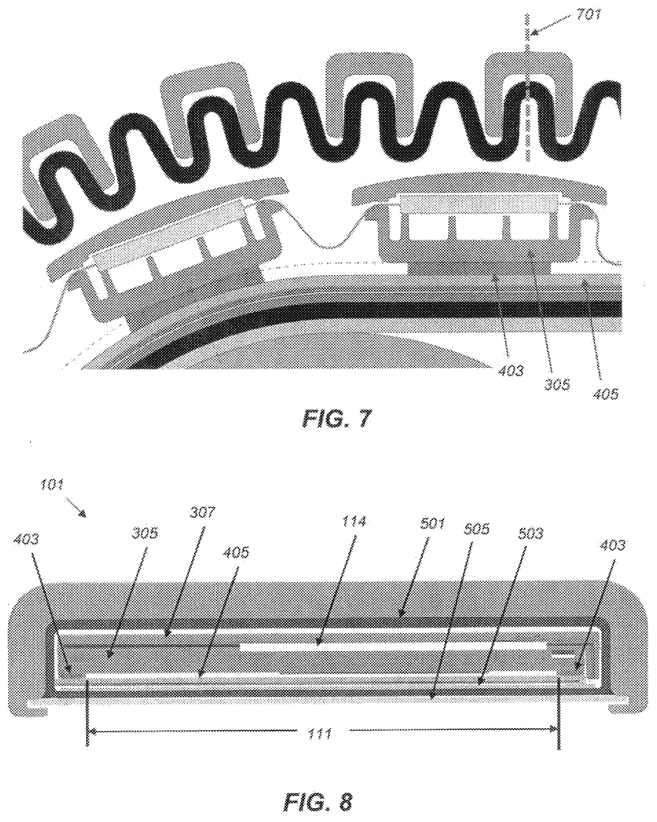

FIG. 4A shows a close-up cross-section side view of the board mounts 305 and board covers 307, which may each comprise a fairly rigid plastic material and are configured to at least partially enclose the read out boards 114. The expanded close-up view of FIG. 4B shows the layers of the imaging sensor 401. The tungsten layer 405 is a thicker, flexible elastomeric layer infused with tungsten particles to attenuate x-ray scatter, as described herein, and to prevent radiation damage to sensitive detector components while being able to bend around a two inch (2″) diameter pipe. The plastic board mounts 305 and board covers 307 secure the read out circuit boards or chips 114 in position, and the foam two-sided adhesive tape 403 provides flexibility while being compressed (see e.g., FIG. 7) when the DR detector 101 is wrapped around an object for imaging. A stainless steel layer 409 is laminated via adhesive 407 on both sides of the stainless steel layer 409 directly to the thin imaging layer 117 and to the tungsten layer 405. This stainless steel layer 409, at a thickness of about 0.006 in. of tempered stainless steel, stabilizes the imaging layer 117 and the overall imaging sensor 401 layers from over-stretching and isolates the stretch forces from the substantially rigid board mounts 305. A thin layer of adhesive 407 attaches the scintillator layer 413 to the imaging layer 117.

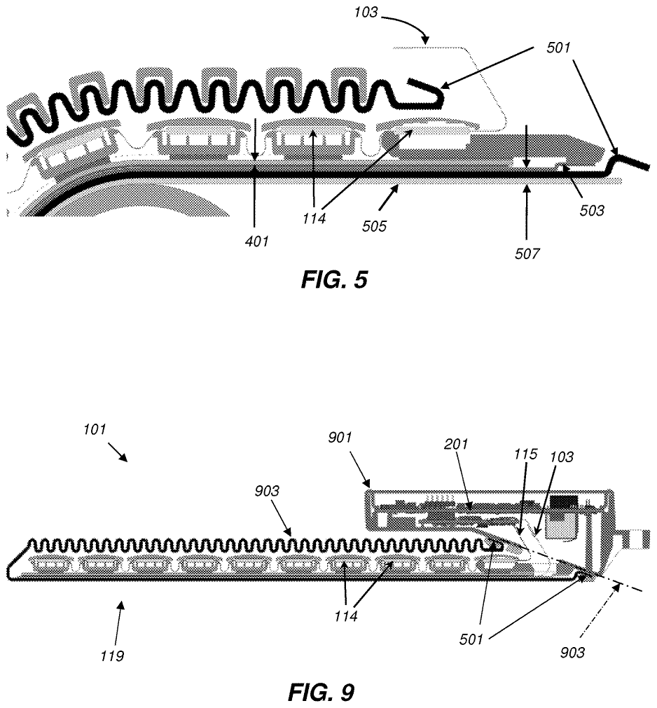

FIG. 5 shows a close-up view of features similar to those shown in FIG. 3B, including close-up details of the DR detector 101 wherein the laminated layers of the imaging sensor 401 are shown coupled to free moving, or slidable, protective layers 507 (including layers 501, 503, 505) as follows. A continuous, flexible one-piece boot 501 is shown surrounding the imaging sensor layers 401, which are laminated layers, and the secured, enclosed, read out boards 114, see e.g., FIGS. 3A-3B for the configured continuous structure of boot 501. Free moving, or slidable, layers 507 comprise an inner sensor shield 503 adjacent to the laminated imaging sensor 401 on one side and the flexible one piece boot 501 on the other side. A replaceable outer boot protector layer 505 adjacent the one-piece boot 501 is configured for preventing abrasion or puncturing of the one-piece boot 501. The outer boot protector layer 505 is easily replaceable in the field and may be considered a sacrificial layer when the DR detector 101 is used to image objects having jagged, serrated, damaged, or otherwise abrasive surfaces. The laminated layers of the imaging sensor 401 consist primarily of the scintillator 413, imaging layer 117, stainless support 409, and elastomeric layer infused with tungsten 405 as described with respect to FIG. 4B. The free moving, slidable, layers consist primarily of inner and outer protective/shield layers, 503, 505, respectively, and the flexible one-piece boot 501.

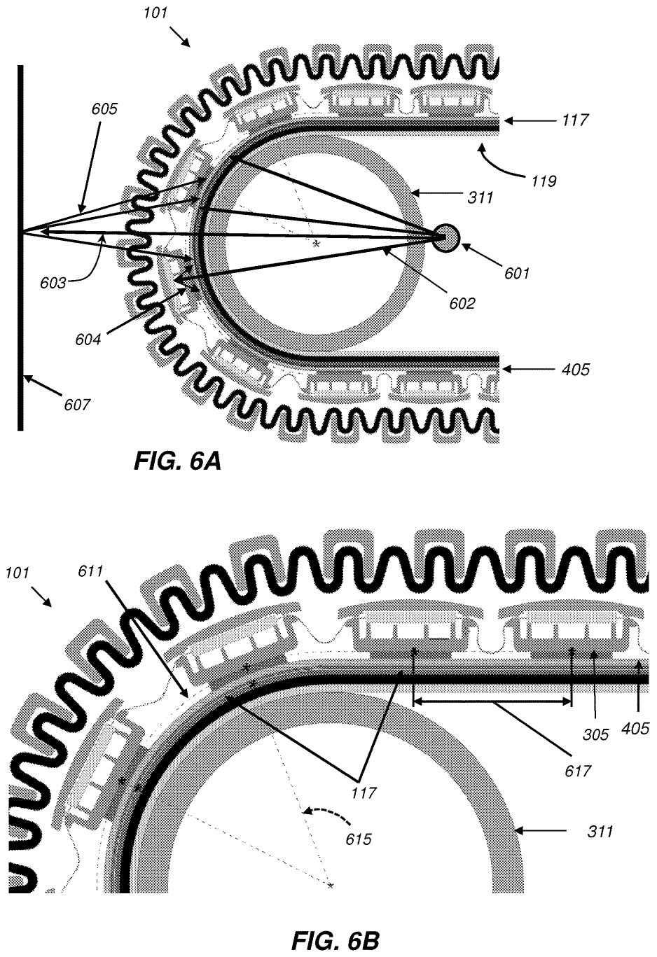

FIG. 6A illustrates a radiographic object imaging set-up whereby a portion of the DR detector 101 is wrapped around one side of an exemplary manufactured object, such as a pipe 311, and an x-ray or gamma ray radiation source 601 is positioned approximately at an opposite side of the object relative to where the DR detector's imaging side 119 is in contact with the object. The attenuation effect of the tungsten infused layer 405 is shown to reduce scatter radiation 605 reflected from external objects 607 and scatter radiation 604 reflected from internal detector components. For example, when imaging dense materials it may be necessary to use high energy x-rays, e.g., 602, 603, with long exposure times. These x-rays can pass through some or all DR detector 101 components, such as exemplary x-rays 602, 603, and result in both internal radiation scatter 604 from detector components and external back scatter radiation 605 from objects 607 external to the DR detector 101. The infused tungsten layer 405 allows some x-rays to pass through but blocks lower energy scatter 604, 605, from coming back through and impacting the imaging layer 117.

FIG. 6B is a close-up view of FIG. 6A, wherein the outer, thicker, flexible tungsten infused elastomer layer 405 allows the DR detector to be bent more easily because this outer layer 405 is stretchable, and consequently it allows the board mounts 305 to separate as described above. This stretchability allows the DR detector to retain a shape sufficient to maintain contact with the pipe 311, in this example. To illustrate this effect, with respect to FIG. 6B, note that in the flat area of the DR detector the pitch distance 617 at the imaging layer 117 and at the board mounts (shown by asterisks) are the same. When the DR detector 101 is bent, the arc length 615 at the imaging layer 117 (shown by asterisks) still equals the flat area imaging layer 117 pitch distance 617, however, the arc length, shown by dashed line 611, at the board mounts (shown by asterisks) is longer than the flat area pitch distance 617 between the board mounts.

FIG. 7 illustrates a method of attaching the board mounts 305 to the tungsten infused elastomeric layer 405. A pressure sensitive tape 403, as illustrated in FIG. 4B, with a foam core and adhesive on both sides may be used to attach the board mounts 305 to the tungsten infused elastomeric layer 405. The foam is selected to be elastic enough to stretch in both directions and to accommodate the resulting bend of the DR detector 101 during an object imaging set-up while maintaining the radial alignment of the board mounts 305 to the imaging sensor layer 401.

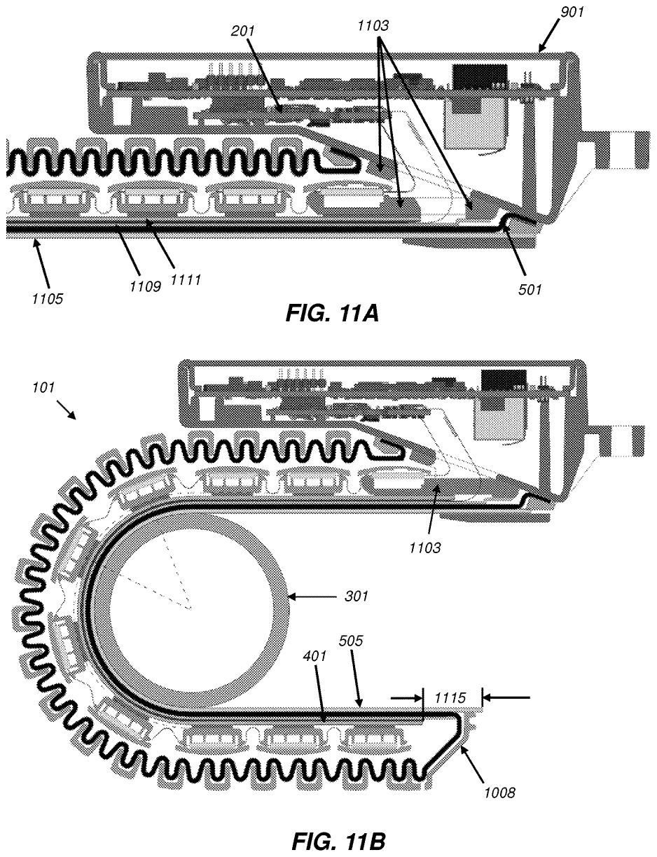

FIG. 8 shows a cross-section view of the DR detector 101 along the non-bending direction in the plane shown by the dashed line 701 in FIG. 7 and in FIG. 11C. The location of the adhesive tape 403 as described herein relative to the active or useable imaging area 111 of the DR detector 101 are indicated, as well as locations of other DR detector components described herein.

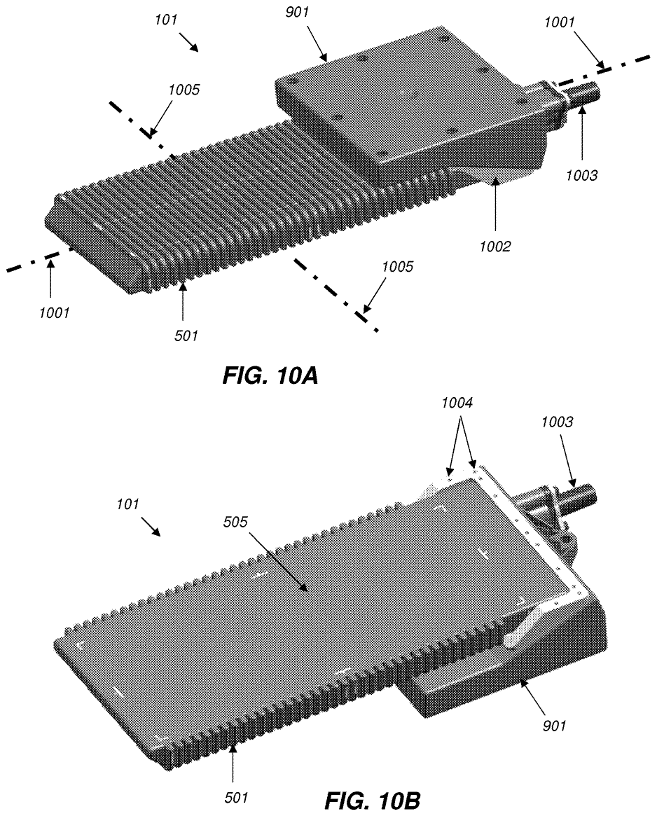

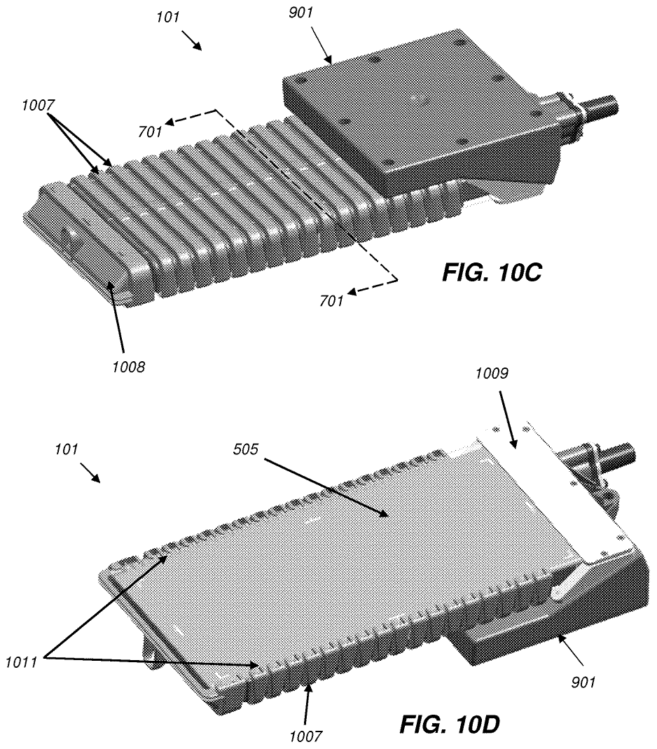

FIG. 9 illustrates a lengthwise cross-section view of the DR detector 101 with PCB housing 901 attached. The one-piece boot 501, described herein in relation to FIG. 5, is shown surrounding the internal components of the DR detector 101. The one piece boot 501 is pleated 903 along the back side of the DR detector 101 to provide slack or flexibility to wrap around a 2″ diameter pipe, and it provides a water barrier for the imaging sensor components. Surfaces of the PCB housing are coplanar in plane 903 to facilitate sealing or clamping ends of the one-piece boot 501 to the housing 901 surfaces using a compression plate 1002 (FIG. 10A) that may be attached to the PCB housing 901 using screws. Also shown is PCB 201 electrically connected to the row driver boards 114 using flex connector 115.

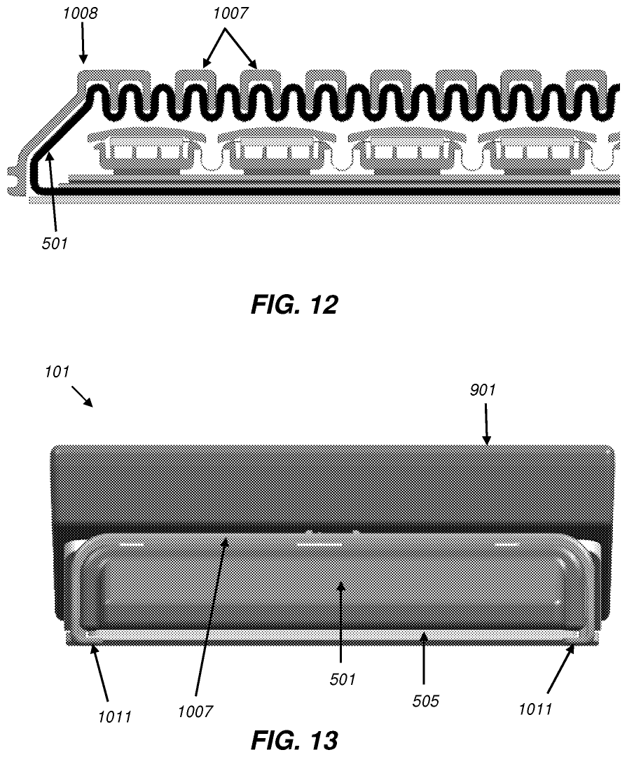

FIGS. 10A and 10B illustrate perspective views of the back side and front side (imaging sensor side), respectively, of the bendable DR detector 101 with the elastomeric one-piece boot 501 shown surrounding the internal components of the DR detector 101 described herein. A replaceable flexible polymer layer as an exemplary outer boot protector layer 505 described herein is on the imaging sensor side. Data and power cable 1003 is shown as well as the PCB housing 901 described herein. The DR detector 101 is flexible and bendable along (not around) the axis 1001 and is rigid along the axis 1005 to prevent bending, which axes are generally perpendicular. When the bendable DR detector 101 is positioned in a standard orientation around a pipe 311 for purposes of radiographically imaging the pipe 311, the rigid axis 1005 may be considered to be parallel to a longitudinal axis of the pipe 311. FIGS. 10C and 10D show a protective exoskeleton with individual backbones 1007 with an end cap 1008 designed to be attached to the one-piece boot 501. Each individual backbone 1007 is configured to be attached to and cover every other individual pleat 903, as shown in FIG. 12, while the end cap 1008 covers two pleats 903 and the front end of the protective boot 501. A hard stainless steel plate 1009 and protective layer 505 described herein are positioned on the imaging sensor side. The hard stainless steel plate 1009 is attached using screws through the plate 1009 into screw holes 1004 shown in FIG. 10B. The backbones 1007 extend around the elastomeric boot 501 with terminal ends 1011 over the peripheral edges of the outer boot protective layer 505, as shown in cross-section in FIG. 14.

FIG. 11A shows a method of attaching the PCB housing 901 to the one-piece boot 501 so that the imaging sensor components remain electrically connected to the electronics in the PCB housing. The portion of the DR detector 101 that is surrounded by the one-piece protective boot 501, generally the imaging components described herein, is attached to the PCB housing 901 using a fixed interface block 1103 having rigid portions that are affixed to the PCB housing 901 using screws or similar means, adhesive, mating connectors, and the like, or a combination thereof. The cross-section view of FIG. 11A shows openings through the fixed rigid block 1103 to allow electrical connections to pass through to the PCB 201 while FIG. 11B shows another cross-section view with a continuous block portion. FIG. 11B shows the bendable DR detector 101 wrapped around an exemplary pipe 301. The free moving, protective, slidable layers 507 described herein can slide or stretch relative to the imaging sensor 401 laminated layers to allow optimal flexibility for the DR detector 101. The laminated imaging sensor 401 is the least stretchable portion of the layers in the bendable DR detector 101 because it is comprised of laminated layers including the thin stainless steel layer 409, however, the outer layer having the tungsten infused elastomer 405 in the lamination does stretch because it is further from the stainless steel layer 409. FIG. 11B illustrates the separation distance 1115 between an end of the protective layer 505 and an end of the imaging sensor 401 laminated layers that occurs when the DR detector 101 is wrapped around an object to be imaged. The end cap 1008 is purposely positioned to allow the protective layer 505 to bypass the end cap 1008.

FIG. 12 shows a close-up view of the exoskeleton backbones 1007 and end cap 1008 which are removable and replaceable. FIG. 13 is a front view of the bendable detector 101 with end cap removed, exposing the one-piece boot 501, and illustrating how the polymer outer protective layer 505 helps to interlock the terminal ends 1011 of the back bones 1007 to the one-piece boot.

As will be appreciated by one skilled in the art, aspects of the present invention may be embodied as an apparatus and a method. Accordingly, aspects of the present invention may take the form of an entirely hardware embodiment, or an entirely method embodiment. Software aspects (including firmware, resident software, micro-code, etc.), or an embodiment combining software and hardware aspects that may all generally be referred to herein as a “service,” “circuit,” “circuitry,” “module,” “circuit board,” “board,” “driver,” “printed circuit board (PCB),” “electronics” and/or “system.”

Any combination of one or more computer readable medium(s) may be utilized for digital image readout from the DR detector described herein. The computer readable medium may be a computer readable signal medium or a computer readable storage medium, such as for storing image data that is read out and/or transmitted under program control. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more conductive wires such as a cable or ribbon or CoF, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device. Program code and/or executable instructions embodied on a computer readable medium may be transmitted using any appropriate medium, including but not limited to wireless, wireline, optical fiber cable, RF, etc., or any suitable combination of the foregoing.

Readout code may execute entirely on a user's computer (device), partly on the user's computer, partly on the user's computer and partly on the bendable DR detector, or on a remote computer or entirely on the remote computer or server. In the latter scenario, the remote computer may be connected to the user's computer or to the bendable DR detector through any type of network, including a local area network (LAN) or a wide area network (WAN), or the connection may be made to an external computer (for example, through the Internet using an Internet Service Provider).

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A flexible digital radiographic detector comprising:
a back side comprising a plurality of adjacent rigid backbones;
a plurality of flexible laminated layers including an imaging sensor layer, wherein an imaging side of the imaging sensor layer faces away from the back side;
a plurality of flexible slidable layers including an elastomeric protective layer, the plurality of flexible slidable layers adjacent to the flexible laminated layers; and
readout electronics electrically attached to the imaging sensor layer and positioned between the back side and the plurality of flexible laminated layers;
wherein the plurality of adjacent rigid backbones are configured to allow the flexible digital radiographic detector to bend around a first axis and to prevent the flexible digital radiographic detector from bending around a second axis perpendicular to the first axis.

2. A method of radiographically imaging a manufactured object comprising the steps of:
wrapping a flexible digital radiographic detector around a first side of the manufactured object such that the digital radiographic detector is abutting the first side of the manufactured object, the digital radiographic detector comprising a plurality of imaging sensor layers and a plurality of protective layers adjacent the imaging sensor layers; and
positioning a radiation source at a second side of the manufacture object generally opposite the first side;
wherein a first end of the imaging sensor layers are coextensive with a first end of the protective layers before the step of wrapping, and wherein the first end of the protective layers extends beyond the first end of the imaging sensor layers after the step of wrapping.

3. The method of claim 2, wherein the step of wrapping comprises wrapping the flexible digital radiographic detector around a circular two inch diameter manufactured object.

4. The detector of claim 1, wherein each of the backbones includes a long side and a shorter transverse side, and wherein the plurality of adjacent rigid backbones are arranged parallel in a row with the long sides adjacent.

5. The detector of claim 1, wherein the plurality of rigid backbones are generally parallel to the first axis when the flexible digital radiographic detector is bent around the first axis.

6. The detector of claim 1, further comprising a flexible one-piece boot having a corrugated side adjacent and inside the plurality of rigid backbones, wherein each rigid backbone is positioned on a ridge of the corrugated one-piece boot.

7. The detector of claim 6, wherein the plurality of rigid backbones are positioned on alternating ridges of the corrugated side of the one-piece boot.

8. The detector of claim 6, wherein the plurality of flexible laminated layers is enclosed by the one-piece boot.

9. The detector of claim 6, wherein the one-piece boot includes a flat side opposite the corrugated side.

10. The detector of claim 9, wherein the plurality of flexible sliding layers includes the flat side of the one-piece boot.

11. The detector of claim 10, wherein the plurality of flexible sliding layers further includes a first slidable layer adjacent an inside surface of the flat side of the one-piece boot and a second slidable layer adjacent an outside surface of the flat side of the one-piece boot.

12. The detector of claim 11, wherein the second slidable layer is configured to slide against the outside surface of the flat side of the one-piece boot 1 as the flexible digital radiographic detector is bent around the first axis.

13. The detector of claim 1, wherein the plurality of flexible laminated layers further includes an elastomeric layer infused with tungsten.

14. The detector of claim 1, wherein the plurality of flexible laminated layers further includes a scintillator layer and a stainless steel layer.

15. The detector of claim 14, wherein the scintillator layer is adhered to a first side of the imaging sensor layer and the stainless steel layer is adhered to a second side of the imaging sensor layer opposite the first side.

16. The detector of claim 15, wherein the plurality of flexible laminated layers further includes an elastomeric layer infused with tungsten adhered to the stainless steel layer.

17. The detector of claim 1, further comprising a plurality of read out boards or chips containing the readout electronics attached to one of the plurality of flexible laminated layers.

18. The detector of claim 13, further comprising a plurality of read out boards or chips containing the readout electronics, the plurality of readout boards or chips attached to the elastomeric layer infused with tungsten.

19. The detector of claim 18, further comprising a two-sided foam adhesive tape for attaching the plurality of readout boards or chips to the elastomeric layer infused with tungsten.

20. The detector of claim 19, further comprising a plurality of board mounts for enclosing each of the plurality of readout boards or chips, the plurality of board mounts adhered to the elastomeric layer infused with tungsten using the two-sided foam adhesive tape.
